(19) United States
(12) Patent Application Publication
(10) Pub. No.: US 2020/0379348 A1
(43) Pub. Date: Dec. 3, 2020

(54) PATTERN-FORMING METHOD AND RADIATION-SENSITIVE COMPOSITION

(71) Applicant: JSR CORPORATION, Tokyo (JP)

(72) Inventor: Hitoshi OSAKI, Tokyo (JP)

(73) Assignee: JSR CORPORATION, Tokyo (JP)

(21) Appl. No.: 16/905,946

(22) Filed: Jun. 19, 2020

Related U.S. Application Data
(63) Continuation of application No. PCT/JP2018/048341, filed on Dec. 27, 2018.
(60) Provisional application No. 62/610,653, filed on Dec. 27, 2017.

(51) Int. Cl. G03F 7/039; G03F 7/038; G03F 7/004; C08F 212/08; C09D 125/14

(52) U.S. Cl. CPC G03F 7/039; G03F 7/038; C09D 125/14; C08F 212/08; G03F 7/0045

(57) ABSTRACT

A pattern-forming method includes: applying a radiation-sensitive composition containing a polymer and a radiation-sensitive acid generating agent on a surface of a substrate to form a coating film on the surface of the substrate; exposing the coating film; and developing the coating film exposed. The polymer has a first structural unit represented by formula (1). In the formula (1), R¹ represents a hydrogen atom, a methyl group, a fluorine atom, or a trifluoromethyl group; and A represents a monovalent organic group having a nitrogen atom.

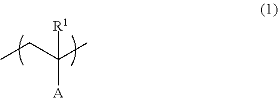

### CROSS-REFERENCE TO RELATED APPLICATIONS

The present application is a continuation application of International Application No. PCT/JP2018/048341, filed Dec. 27, 2018, which claims priority to U.S. Provisional Patent Application No. 62/610,653, filed Dec. 27, 2017. The contents of these applications are incorporated herein by reference in their entirety.

### BACKGROUND OF THE INVENTION

### Field of the Invention

The present invention relates to a pattern-forming method and a radiation-sensitive composition.

### Discussion of the Background

In a field of microfabrication typified by production of integrated circuit devices, fine resist patterns are conventionally formed by: providing a resist coating film on a substrate with a resin composition containing a polymer having an acid-labile group;

exposing the resist coating film by irradiation with a radioactive ray having a short wavelength such as an excimer laser through a mask pattern; and removing a light-exposed site with an alkaline developer solution. This process involves using a “chemically amplified resist” in which a radiation-sensitive acid generating agent that generates an acid by irradiation with a radioactive ray is contained in the resin composition to improve the sensitivity by the action of the acid.

In this field, microfabrication of structures of various types of electronic devices such as semiconductor devices and liquid crystal devices has been accompanied by demands for miniaturization of patterns formed.

Meanwhile, to meet such demands, a directed self-assembly lithography process which utilizes a phase separation structure constructed through directed self-assembly, as generally referred to, that spontaneously forms an ordered pattern has been proposed. As such a directed self-assembly lithography process, a process for forming an ultrafine pattern by directed self-assembly using a block copolymer formed by copolymerization of monomers having different properties from one another is known (see Japanese Unexamined Patent Application, Publication No. 2008-149447). Moreover, formation of a finer pattern by a directed self-assembly (DSA) lithography process with a chemo-epitaxy process in which the resist pattern described above is used as a guide pattern, and arrangement of domains of block copolymers is controlled by spatial arrangement defined by the guide pattern has also been investigated in recent years (see Japanese Unexamined Patent Application (Translation of PCT Application), Publication No. 2014-528015).

However, in pattern formation using the chemically amplified resist, controlling a diffusion length of the acid derived from the radiation-sensitive acid generating agent is difficult, thereby hampering advancement of further miniaturization. Additionally, the directed self-assembly lithography process requires a plurality of steps in producing a substrate, and thus improvement of throughput in the process of forming a fine pattern, as well as further improvement in inhibition of guide pattern defects has been demanded.

### SUMMARY OF THE INVENTION

According to an aspect of the present invention, a pattern-forming method includes applying a radiation-sensitive composition including a polymer and a radiation-sensitive acid generating agent on a surface of a substrate to form a coating film on the surface of the substrate. The coating film is exposed. The coating film exposed is developed. The polymer includes a first structural unit represented by formula (1).

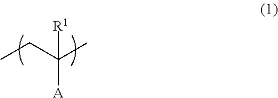

In the formula (1), R¹ represents a hydrogen atom, a methyl group, a fluorine atom, or a trifluoromethyl group; and A represents a monovalent organic group having a nitrogen atom.

According to another aspect of the present invention, a pattern-forming method includes forming a fine pattern constituted from a directed self-assembling material including a block copolymer, using the pattern formed by the above-mentioned pattern-forming method as a guide pattern.

According to further aspect of the present invention, a radiation-sensitive composition includes a polymer including a first structural unit represented by formula (1) at at least one end of a main chain thereof; and a radiation-sensitive acid generating agent.

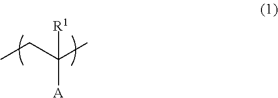

In the formula (1), R¹ represents a hydrogen atom, a methyl group, a fluorine atom, or a trifluoromethyl group; and A represents a monovalent organic group having a nitrogen atom.

### BRIEF DESCRIPTION OF THE DRAWINGS

FIG. 1 is a view for explaining a mechanism for grafting a polymer to a surface of a substrate by the pattern-forming method of the embodiment of the present invention;

FIG. 2 is a schematic view illustrating one example of a state after laminating a coating film on the substrate in the pattern-forming method of the embodiment of the present invention;

FIG. 3 is a schematic view illustrating one example of a state after forming a pattern for a mask for carrying out an exposing step in the pattern-forming method of the embodiment of the present invention;

FIG. 4 is a schematic view illustrating one example of a state after etching the coating film through the pattern for the mask in the pattern-forming method of the embodiment of the present invention; and

FIG. 5 is a schematic view illustrating one example of a state of the substrate on which the guide pattern has been formed in the pattern-forming method of the embodiment of the present invention.

### DESCRIPTION OF EMBODIMENTS

According to one embodiment of the invention, a pattern-forming method includes: applying a radiation-sensitive composition containing a polymer and a radiation-sensitive acid generating agent on a surface of a substrate; exposing a coating film of the radiation-sensitive composition formed by the applying; and developing the coating film of the radiation-sensitive composition exposed, wherein the polymer comprises a first structural unit represented by formula (1):

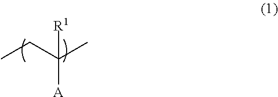

wherein, in the formula (1), R¹ represents a hydrogen atom, a methyl group, a fluorine atom, or a trifluoromethyl group; and A represents a monovalent organic group having a nitrogen atom.

According to another embodiment of the present invention, a radiation-sensitive composition contains: a polymer having a first structural unit represented by the following formula (1) at no less than one end of a main chain thereof; and a radiation-sensitive acid generating agent,

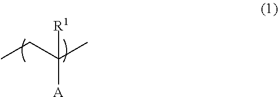

wherein, in the formula (1), R¹ represents a hydrogen atom, a methyl group, a fluorine atom, or a trifluoromethyl group; and A represents a monovalent organic group having a nitrogen atom.

The “organic group” as referred to herein means a group that includes at least one carbon atom. The “main chain” as referred to herein means a longest atom chain of a polymer. The “pattern” as referred to herein means a patterned fine structure obtained by the pattern-forming method of the embodiment of the invention, and may include a guide pattern. The “end of a main chain” as referred to herein means a part of a main chain including a terminal end.

According to the pattern-forming method and the radiation-sensitive composition of the embodiments of the present invention, a fine pattern can be conveniently formed without diffusion of an acid due to not involving the chemically amplified type. Furthermore, in a case in which directed self-assembly is carried out using a chemo-epitaxy process, throughput in a fine pattern-forming process can be improved, and a guide pattern superior in orientation characteristics of the phase separation structure by directed self-assembly can be formed.

Hereinafter, the pattern-forming method and the radiation-sensitive composition of the embodiments of the invention will be described in detail.

### Pattern-Forming Method

The pattern-forming method of the embodiment of the present invention includes: a step of applying a radiation-sensitive composition (hereinafter, may be also referred to as “radiation-sensitive composition (I)”) containing a polymer (hereinafter, may be also referred to as “(A) polymer” or “polymer (A)”) and a radiation-sensitive acid generating agent (hereinafter, may be also referred to as “(B) acid generating agent” or “acid generating agent (B)”) on a surface of a substrate (hereinafter, may be also referred to as “applying step”); a step of exposing a coating film of the radiation-sensitive composition formed by the applying step (hereinafter, may be also referred to as “exposing step”); and a step of developing the coating film of the radiation-sensitive composition exposed (hereinafter, may be also referred to as “developing step”), in which the polymer (A) has a first structural unit (hereinafter, may be also referred to as “structural unit (I)”) represented by the following formula (1).

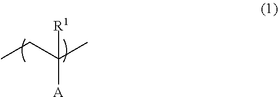

In the above formula (1), R¹ represents a hydrogen atom, a methyl group, a fluorine atom, or a trifluoromethyl group; and A represents a monovalent organic group having a nitrogen atom (hereinafter, may be also referred to as “side chain group (I)”).

It is preferred that the pattern-forming method of the embodiment of the invention further includes, before the exposing step or after the exposing step, and before the developing step, a step of heating the coating film formed by the applying step (hereinafter, may be also referred to as “heating step”). Moreover, the pattern-forming method of an embodiment of the invention may further include a step of forming a fine pattern constituted from a directed self-assembling material containing a block copolymer, using a pattern formed by the pattern-forming method of the embodiment of the invention as a guide pattern (hereinafter, may be also referred to as “fine pattern-forming step with a guide pattern”).

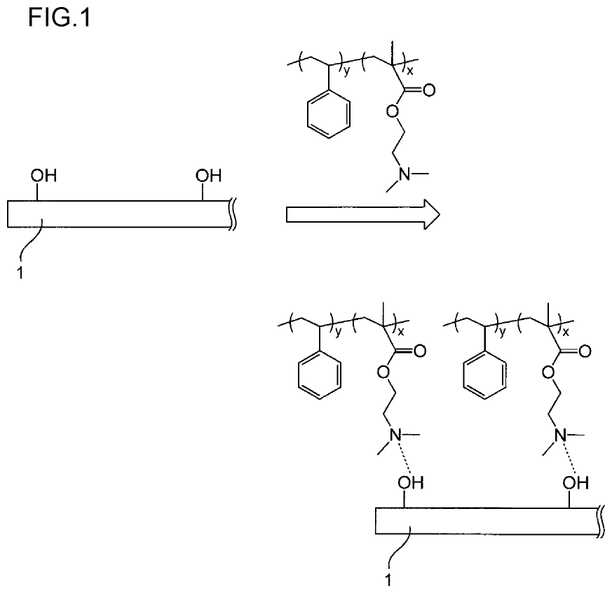

Due to including each step described above, and due to the radiation-sensitive composition (I) containing the polymer (A), the pattern-forming method of the embodiment of the invention enables a fine pattern to be conveniently formed. In addition, in the case in which directed self-assembly with the chemo-epitaxy process is carried out, throughput in the fine pattern-forming process can be improved, and a guide pattern superior in orientation characteristics of the phase separation structure by directed self-assembly can be formed. Moreover, since a chemical amplification effect between a component having an acid-labile functional group and a radiation-sensitive acid generating agent capable of generating an acid by irradiation with a radioactive ray (hereinafter, may be also referred to as “exposure”) is not utilized, a pattern with high resolution can be formed. Although not necessarily clarified and without wishing to be bound by any theory, the reason for achieving the effects described above due to the pattern-forming method involving the aforementioned constitution may be supposed as in the following, for example. As shown in FIG. 1, a mechanism of grafting of the polymer (A) to the surface of the substrate is presumed to be an interaction by means of a hydrogen bond between the surface of the substrate and the side chain group (I) of the structural unit (I) of the polymer (A), and it is considered that owing to the nitrogen atom in the side chain group (I) of the structural unit (I), the polymer (A) exhibits very strong grafting force (adhesion force) to the surface of the substrate. Meanwhile, an interaction between the surface of the substrate and the side chain group (I) having a nitrogen atom is inhibited by allowing an acid, which has been generated from the acid generating agent by exposure, to act on the surface of the substrate on which the polymer (A) has been grafted, and thus the polymer (A) on the surface of the substrate can be selectively desorbed. It is considered that a fine pattern can be conveniently formed as a result, thereby demonstrating the effect. It is to be noted in FIG. 1, “x” represents a proportion (mol %) of the structural unit (I) contained with respect to total structural units in the polymer (A), whereas “y” represents a proportion (mol %) of the other structural unit contained with respect to total structural units in the polymer (A).

Hereinafter, each step will be described.

### Applying Step

In this step, the radiation-sensitive composition (I) containing the polymer (A) and the acid generating agent (B) is applied.

As the substrate, for example, silicon and a silicon-containing oxide may be exemplified. Exemplary silicon-containing oxides include a silicon oxide, a hydrolytic condensation product of a hydrolyzable silane, a silicon carboxide, a silicon oxynitride, and the like.

Examples of silicon oxide include SiO₂ (silicon dioxide), and the like.

Examples of the hydrolytic condensation product of the hydrolyzable silane include hydrolytic condensation products of tetraalkoxysilane such as tetraethoxysilane (TEOS), and the like.

Examples of the silicon carboxide include SiOC, and the like.

Examples of the silicon oxynitride include SiON, and the like.

Of these, silicon dioxide is preferred.

The shape of the substrate is not particularly limited, and the substrate may have a desired shape as appropriate, such as platy or spherical. A size of the substrate is not particularly limited, and the regions may have an appropriate desired size.

It is preferred that the surface of the substrate is washed beforehand with, for example, an about 5% by mass aqueous citric acid solution.

The application procedure of the radiation-sensitive composition (I) may be, for example, spin coating, or the like.

### Radiation-Sensitive Composition (I)

The radiation-sensitive composition (I) contains the polymer (A) and the acid generating agent (B). The radiation-sensitive composition (I) may also contain, in addition to the polymer (A) and the acid generating agent (B), a solvent (hereinafter, may be referred to as “(C) solvent” or “solvent (C)”) as a favorable component, and within a range not leading to impairment of the effects of the present invention, other component(s) may be contained. Each component will be described in the following.

### (A) Polymer

The polymer (A) has the structural unit (I). It is preferred that the polymer (A) has a second structural unit (hereinafter, may be also referred to as “structural unit (II)”) described later. Furthermore, the polymer (A) may also have a structural unit other than the structural unit (I) and the structural unit (II) (other structural unit). The polymer (A) may have one, or two or more types of each structural unit. The structural unit (I), the structural unit (II), and the like are as described below.

It is preferred that the polymer (A) has the first structural unit at no less than one end of a main chain thereof. When the polymer (A) has the first structural unit at no less than one end of a main chain thereof, an interaction with the substrate is enabled, and thus a pattern superior in positional selectivity to a desired site can be conveniently formed.

### Structural Unit (I)

The structural unit (I) is represented by the following formula (1).

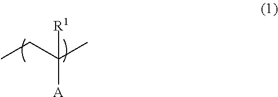

In the above formula (1), R¹ represents a hydrogen atom, a methyl group, a fluorine atom, or a trifluoromethyl group; and A represents a side chain group (I).

R¹ represents, in light of a degree of copolymerization of a monomer that gives the structural unit (I), a hydrogen atom or a methyl group, and more preferably a methyl group.

The side chain group (I) represents a monovalent organic group having a nitrogen atom. The nitrogen atom (A) in the side chain group (I) preferably has an unshared electron pair.

The nitrogen atom (A) having the unshared electron pair is exemplified by: a nitrogen atom to which one to three atom(s) other than a hydrogen atom bonds/bond via a single bond; a nitrogen atom in an aromatic heterocyclic group; and the like.

Examples of the side chain group (I) include: a group (α) that includes a divalent nitrogen atom-containing group between two adjacent carbon atoms of a monovalent hydrocarbon group having 1 to 20 carbon atoms; a group obtained by substituting a part or all of hydrogen atoms included in the hydrocarbon group and group (α) with a monovalent nitrogen atom-containing group; and the like. The side chain group (I) may further include a divalent group containing a hetero atom other than a nitrogen atom between two adjacent carbon atoms of the hydrocarbon group, and/or a part or all of the hydrogen atoms included in the hydrocarbon group and the group (α) may be further substituted with a monovalent group containing a hetero atom other than a nitrogen atom.

The “hydrocarbon group” as referred to herein may include a chain hydrocarbon group, an alicyclic hydrocarbon group and an aromatic hydrocarbon group. The “hydrocarbon group” may be either a saturated hydrocarbon group or an unsaturated hydrocarbon group. The “chain hydrocarbon group” as referred to herein means a hydrocarbon group not including a cyclic structure but being constituted with only a chain structure, and both a linear hydrocarbon group and a branched hydrocarbon group may be included. The “alicyclic hydrocarbon group” as referred to herein means a hydrocarbon group that includes, as a ring structure, not an aromatic ring structure but an alicyclic structure alone, and may include both a monocyclic alicyclic hydrocarbon group and a polycyclic alicyclic hydrocarbon group. However, it is not necessary for the alicyclic hydrocarbon group to be constituted with only an alicyclic structure; it may include a chain structure in a part thereof. The “aromatic hydrocarbon group” as referred to herein means a hydrocarbon group that includes an aromatic ring structure as a ring structure. However, it is not necessary for the aromatic hydrocarbon group to be constituted with only an aromatic ring structure; it may include a chain structure or an alicyclic structure in a part thereof. The number of “ring atoms” as referred to herein means the number of atoms constituting the ring in an alicyclic structure, an aromatic ring structure, an aliphatic heterocyclic structure or an aromatic heterocyclic structure, and in the case of a polycyclic ring structure, the number of “ring atoms” means the number of atoms constituting the polycyclic ring.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylmethyl group and an anthrylmethyl group; and the like.

Examples of the divalent nitrogen atom-containing group include —NH—, —NR′—, —CH═N—, and the like, wherein R′ represents a monovalent hydrocarbon group having 1 to 10 carbon atoms.

Examples of the monovalent nitrogen atom-containing group include —NH₂, —NHR″, —NR″₂, and the like, wherein each R″ represents a monovalent hydrocarbon group having 1 to 10 carbon atoms, or in —NR″₂, two R″s may taken together represent a ring structure together with the carbon chain to which the two R″s bond.

The hetero atom constituting the monovalent or divalent group containing the hetero atom other than a nitrogen atom is exemplified by an oxygen atom, a sulfur atom, a phosphorus atom, a silicon atom, a halogen atom, and the like. Examples of the halogen atom include a fluorine atom, a chlorine atom, a bromine atom, an iodine atom, and the like.

Examples of the divalent group containing the hetero atom other than a nitrogen atom include —O—, —CO—, —S—, —CS—, a group obtained by combining two or more of these, and the like. Of these, —O— is preferred.

Examples of the monovalent group containing the hetero atom other than a nitrogen atom include: halogen atoms such as a fluorine atom, a chlorine atom, a bromine atom and an iodine atom; a hydroxy group; a carboxy group; a sulfanyl group; and the like.

As the side chain group (I), a group represented by the following formula (i) is preferred.

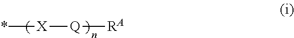

In the above formula (i), X represents a single bond, —COO—, —CO—, —O—, —NH—, —NHCO— or —CONH—; Q represents a single bond or a divalent hydrocarbon group having 1 to 20 carbon atoms; R^{A} represents a monovalent primary, secondary or tertiary amino group having 0 to 20 carbon atoms, or a monovalent nitrogen-containing heterocyclic group having 5 to 20 ring atoms; n is an integer of 0 to 10, wherein in a case in which n is no less than 1, Q does not represent a single bond; and * denotes a binding site to a carbon atom to which R¹ bonds in the above formula (1).

X represents preferably a single bond or —COO—, and more preferably —COO—.

Examples of the divalent hydrocarbon group having 1 to 20 carbon atoms which may be represented by Q include groups similar to the divalent hydrocarbon group having 1 to 20 carbon atoms exemplified as A in the above formula (1), and the like.

Q represents preferably a divalent hydrocarbon group, more preferably an alkanediyl group, and still more preferably an ethanediyl group.

Examples of the monovalent primary, secondary or tertiary amino group having 0 to 20 carbon atoms which may be represented by R^{A} include:

a primary amino group represented by —NH₂;

secondary amino groups such as a methylamino group, an ethylamino group, a cyclohexylamino group, and a phenylamino group;

tertiary amino groups such as a dimethylamino group, a diethylamino group, a dicyclohexylamino group, and a diphenylamino group; and the like.

Examples of the monovalent nitrogen-containing heterocyclic group having 5 to 20 ring atoms which may be represented by R^{A} include:

nitrogen-containing aliphatic heterocyclic groups such as an azacyclopentyl group, an azacyclohexyl group, a 3,3,5,5-tetramethylazacyclohexyl group and an N-methyl-3,3,5,5-tetramethylazacyclohexyl group;

nitrogen-containing aromatic heterocyclic groups such as a pyridyl group, a pyrazyl group, a pyrimidyl group, a pyridazyl group, a quinolyl group, an isoquinolyl group, and a carbazolyl group; and the like.

R^{A} represents preferably a tertiary amino group, and more preferably a dimethylamino group.

In the above formula (i), n is preferably 0 to 2, and more preferably 0 or 1.

Examples of the structural unit (I) include structural units represented by the following formulae (1-1) to (1-15) (hereinafter, may be also referred to as “structural units (I-1) to (I-15)”) and the like.

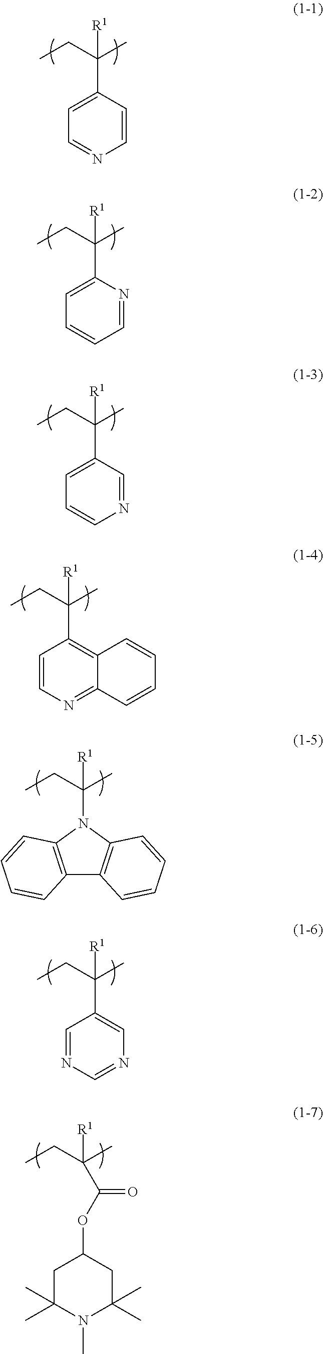

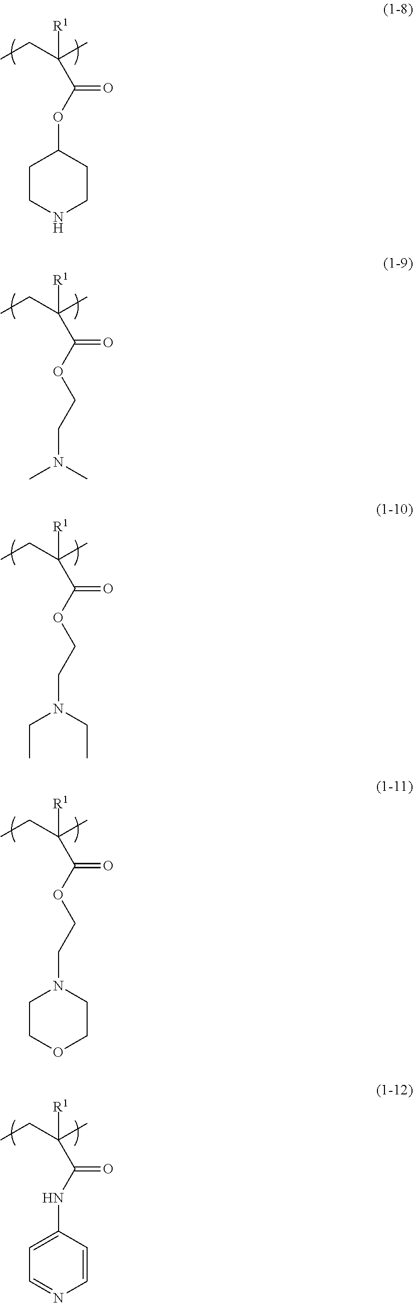

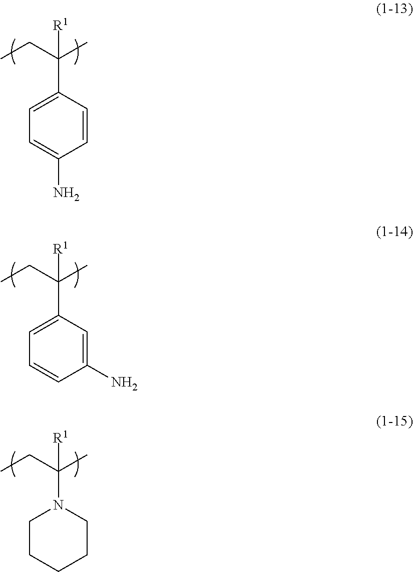

In the above formulae (1-1) to (1-15), R¹ is as defined in the above formula (1).

Of these, the structural unit (I-9) is preferred.

Examples of a monomer that gives the structural unit (I) include: vinyl compounds each including the side chain group (I), such as vinyl pyridine, vinyl pyrazine, vinyl quinoline, vinylaniline, and vinylpiperidine;

styrene compounds each including the side chain group (I), such as aminostyrene and dimethylaminostyrene;

(meth)acrylic acid esters each including the side chain group (I), such as dimethylaminoethyl (meth)acrylate, diethylaminoethyl (meth)acrylate, and N-methyl-3,3,5,5-tetramethylazacyclohexan-1-yl (meth)acrylate; and the like.

A proportion of the structural unit (I) contained with respect to total structural units in the polymer (A) is preferably no less than 0.1 mol %, more preferably no less than 0.5 mol %, still more preferably no less than 1 mol %, and particularly preferably no less than 2 mol %. The proportion of the structural unit (I) is preferably no greater than 30 mol %, more preferably no greater than 20 mol %, still more preferably no greater than 10 mol %, and particularly preferably no greater than 5 mol %. When the proportion of the structural unit (I) falls within the above range, a finer pattern can be conveniently formed.

The structural unit (I) is preferably aligned in a block. The polymer (A) has the block of the structural unit (I) preferably at no less than one end of the main chain, and more preferably at one end of the main chain. When the polymer (A) has the block of the structural unit (I) at one end of the main chain, a finer pattern can be conveniently formed.

### Structural Unit (II)

The structural unit (II) is preferably a structural unit that is different from the first structural unit and is a structural unit (hereinafter, may be also referred to as “structural unit (II-1)”) represented by the following formula (2-1), a structural unit (hereinafter, may be also referred to as “structural unit (II-2)”) represented by the following formula (2-2) or a combination thereof.

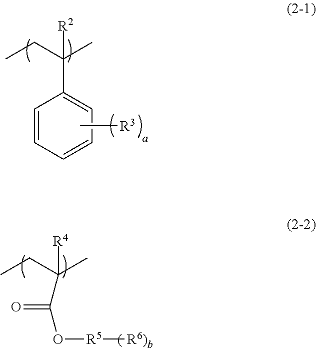

In the above formulae (2-1) and (2-2), R² and R⁴ each independently represent a hydrogen atom, a methyl group, a fluorine atom, or a trifluoromethyl group; R³ represents a monovalent organic group having 1 to 20 carbon atoms; R⁵ represents a hydrocarbon group having 1 to 20 carbon atoms and having a valency of (1+b); R⁶ represents a hydrogen atom or a monovalent group having a hetero atom; a is an integer of 0 to 5, wherein in a case in which a is no less than 2, a plurality of R³s are identical or different from each other; and b is an integer of 1 to 3, wherein in a case in which b is no less than 2, a plurality of R⁶s are identical or different from each other.

In light of a degree of copolymerization of a monomer that gives the structural unit (II), R² represents preferably a hydrogen atom or a methyl group, and more preferably a hydrogen atom.

The monovalent organic group having 1 to 20 carbon atoms represented by R³ is exemplified by a monovalent hydrocarbon group having 1 to 20 carbon atoms, a carboxy group, and the like.

In the above formula (2-1), a is preferably 0 to 2, more preferably 0 or 1, and still more preferably 0.

In light of the degree of copolymerization of the monomer that gives the structural unit (II), R⁴ represents preferably a hydrogen atom or a methyl group, and more preferably a methyl group.

Examples of the hydrocarbon group having 1 to 20 carbon atoms and having a valency of (1+b) which may be represented by R⁵ include groups obtained by removing “b” hydrogen atoms from the monovalent hydrocarbon group exemplified for A in the above formula (1) provided that 1 to 20 carbon atoms are included, and the like.

In the above formula (2-2), b is preferably 1 or 2, and more preferably 1.

Examples of the monovalent group having the hetero atom which may be represented by R⁶ include:

a group having an oxygen atom, such as a hydroxy group or a hydroxymethyl group;

a group having a sulfur atom, such as a sulfanyl group or a sulfanyl methyl group;

a group having a fluorine atom, such as a fluorine atom or a trifluoromethyl group; and the like.

R⁶ represents preferably a hydrogen atom.

It is preferred that the structural unit (II) does not include an acid-labile group. The acid-labile group as referred to herein means a group that is to be dissociated by an acid generated from the radiation-sensitive acid generating agent upon an exposure, thereby yielding a polar group such as a carboxyl group.

The structural unit (II) is exemplified by: a structural unit (II-1) such as structural units represented by the following formulae (2-1-1) to (2-1-3) (hereinafter, may be also referred to as “structural units (II-1-1) to (II-1-3)”); a structural unit (II-2) such as structural units represented by the following formulae (2-2-1) to (2-2-6) (hereinafter, may be also referred to as “structural units (II-2-1) to (II-2-6)”); and the like.

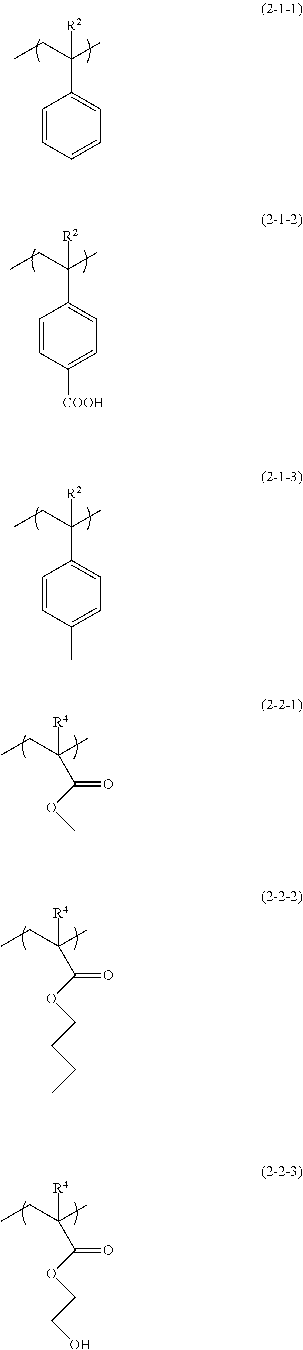

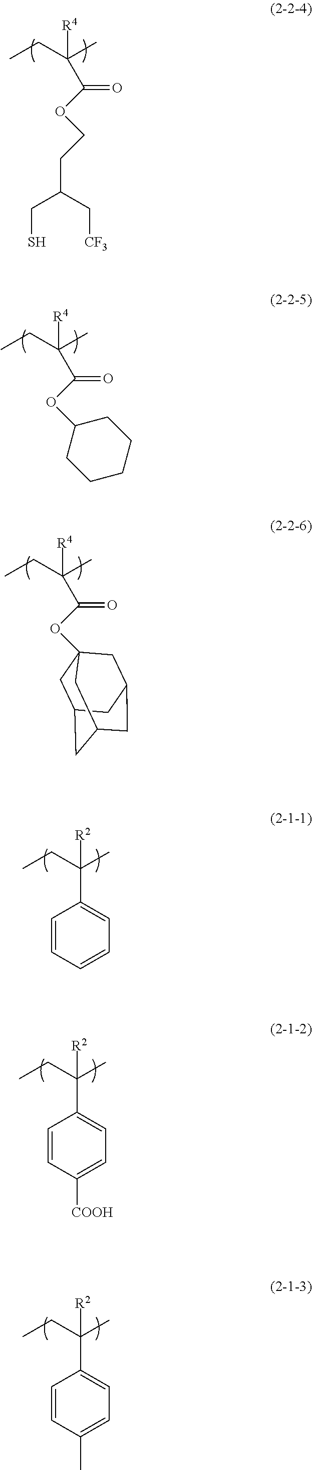

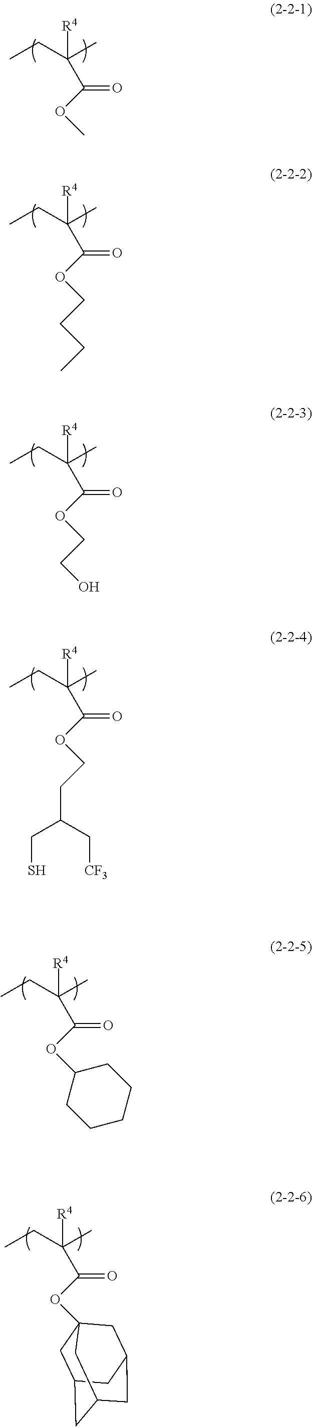

In the above formulae (2-1-1) to (2-1-3), R² is as defined in the above formula (2-1).

In the above formulae (2-2-1) to (2-2-6), R⁴ is as defined in the above formula (2-2).

Of these, the structural units (2-1-1) and (2-2-1) are preferred, and the structural unit (2-1-1) is more preferred.

In the case in which the polymer (A) has the structural unit (II), a proportion of the structural unit (II) contained with respect to total structural units in the polymer (A) is preferably no less than 50 mol %, more preferably no less than 75 mol %, and still more preferably no less than 89 mol %. The proportion of the structural unit (II) is preferably no greater than 99.9 mol %, more preferably no greater than 99 mol %, and still more preferably no greater than 97 mol %. When the proportion of the structural unit (II) falls within the above range, desorption performance can be further improved.

### Other Structural Unit(s)

The polymer (A) may also have other structural unit(s) aside from the structural unit (I) and the structural unit (II). The other structural unit(s) is/are exemplified by a structural unit derived from a substituted or unsubstituted ethylene, and the like (wherein the structural unit (I) and the structural unit (II) are excluded).

In the case in which the polymer (A) has the other structural unit(s), a proportion of the other structural unit(s) contained with respect to total structural units in the polymer (A) is preferably no greater than 20 mol %, more preferably no greater than 5 mol %, and still more preferably no greater than 1 mol %.

### Synthesis Procedure of Polymer (A)

The polymer (A) may be synthesized by, for example, using the monomer that gives the structural unit (I), and as needed the monomer that gives the structural unit (II), etc. to permit polymerization through anionic polymerization, cationic polymerization, radical polymerization or the like in an appropriate solvent. Of these, in order to obtain a polymer having the block of the structural unit (I), living anionic polymerization among types of anionic polymerization; reversible chain transfer polymerization, atom transfer radical polymerization, or control radical polymerization in the presence of nitrooxide, etc. among types of radical polymerization; and the like are more preferred.

Examples of the anionic polymerization initiator which may be used in the living anionic polymerization include:

alkyl lithium, alkylmagnesium halide, sodium naphthalenide, and alkylated lanthanoid compounds;

potassium alkoxides such as t-butoxy potassium;

alkyl zinc such as dimethyl zinc;

alkyl aluminum such as trimethyl aluminum;

aromatic metal compounds such as benzyl potassium; and the like.

Of these, alkyl lithium is preferred.

Examples of the solvent which may be used in the living anionic polymerization include:

alkanes such as n-hexane;

cycloalkanes such as cyclohexane;

aromatic hydrocarbons such as toluene;

saturated carboxylic acid esters such as ethyl acetate, n-butyl acetate, i-butyl acetate and methyl propionate;

ketones such as 2-butanone and cyclohexanone;

ethers such as tetrahydrofuran and dimethoxyethane; and the like.

One, or two or more types of these solvents may be used.

A reaction temperature in the living anionic polymerization may be appropriately selected in accordance with the type of the anionic polymerization initiator, but is preferably no less than −150° C., and more preferably no less than −80° C.; and is preferably no greater than 50° C., and more preferably no greater than 40° C. A reaction time period is preferably no less than 5 min, and more preferably no less than 20 min; and is preferably no greater than 24 hrs, and more preferably no greater than 12 hrs.

The polymer (A) formed by the polymerization is preferably recovered by a reprecipitation technique. More specifically, after completion of the reaction, the reaction liquid is charged into a reprecipitation solvent to recover the intended polymer in a powder form. As the reprecipitation solvent, alcohol, ultra pure water, alkane or the like may be used alone or as a mixture of two or more types thereof. Aside from the reprecipitation technique, a liquid separation operation, a column operation, an ultrafiltration operation or the like may be employed to recover the polymer by removing low-molecular weight components such as monomers and oligomers.

A number average molecular weight (Mn) of the polymer (A) is preferably no less than 1,000, more preferably no less than 2,000, still more preferably no less than 3,000, and particularly preferably no less than 4,000. The number average molecular weight is preferably no greater than 100,000, more preferably no greater than 70,000, still more preferably no greater than 50,000, and particularly preferably no greater than 30,000.

A ratio (dispersity index) of a weight average molecular weight (Mw) to the Mn of the polymer (A) is preferably no greater than 5, more preferably no greater than 2, still more preferably no greater than 1.5, and particularly preferably no greater than 1.1.

A content of the polymer (A) with respect to all components other than the solvent in the radiation-sensitive composition (I) is preferably no less than 60% by mass, and more preferably no less than 80% by mass. The content of the polymer (A) is preferably no greater than 99% by mass.

### (B) Acid Generating Agent

The acid generating agent (B) is a component capable of generating an acid by an action of a radioactive ray. When the radiation-sensitive composition (I) is contained in the acid generating agent (B), an acid is generated by irradiation with a radioactive ray. Therefore, an interaction between the surface of the substrate and the side chain group (I) having a nitrogen atom is inhibited by allowing an acid, which has been generated from the acid generating agent by exposure, to act on the surface of the substrate on which the polymer

(A) has been grafted, and thus the polymer (A) on the surface of the substrate can be selectively desorbed. The radiation-sensitive composition (I) may contain one, or two or more types of the acid generating agent (B).

The acid generating agent (B) is exemplified by an onium salt compound, an N-sulfonyloxyimide compound, a halogen-containing compound, a diazoketone compound, and the like.

Exemplary onium salt compounds include a sulfonium salt, a tetrahydrothiophenium salt, an iodonium salt, an ammonium salt, a phosphonium salt, a diazonium salt, a pyridinium salt, and the like.

Specific examples of the acid generating agent (B) include compounds described in paragraphs [0176] to [0202] of Japanese Unexamined Patent Application, Publication No. 2015-114341, and the like.

Examples of the sulfonium salt include triphenylsulfonium trifluoromethanesulfonate, triphenylsulfonium nonafluoro-n-butanesulfonate, 4-cyclohexylphenyldiphenylsulfonium trifluoromethanesulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium2-bicyclo[2.2.1]hept-2-yl-1,1,2,2-tetrafluoroethanesulfonate, bi s(4-t-butylphenyl)iodonium trifluoromethanesulfonate, and the like.

Examples of the ammonium salt include triethylammonium trifluoromethanesulfonate, triethylammonium nonafluoro-n-butanesulfonate, and the like.

Examples of the phosphonium salt include (1-6-η-cumene) (η-cyclopentadienyl)iron hexafluorophosphonate, and the like.

Examples of the N-sulfonyloxyimide compound include N-(trifluoromethanesulfonyloxy)bicyclo[2.2.1]hept-5-ene-2,3-dicarboxyimide and the like.

The acid generating agent (B) is preferably the onium salt compound, more preferably the sulfonium salt, and still more preferably triphenylsulfonium nonafluoro-n-butanesulfonate.

It is preferred that the acid generating agent (B) is contained in an amount of 50 mol % to 200 mol % with respect to the side chain group (I) having a nitrogen atom in the polymer (A), since selective desorption of the polymer (A) can be efficiently conducted.

A content of the acid generating agent (B) with respect to 100 parts by mass of the polymer (A) is preferably no less than 1 part by mass, more preferably no less than 5 parts by mass, and still more preferably no less than 10 parts by mass. The content of the acid generating agent (B) is preferably no greater than 50 parts by mass, more preferably no greater than 30 parts by mass, and still more preferably no greater than 20 parts by mass.

When the content of the radiation-sensitive acid generating agent falls within the above range, selectivity in forming the coating film of the radiation-sensitive composition (I) can be further improved.

### (C) Solvent

The solvent (C) is not particularly limited as long as it is capable of dissolving or dispersing at least the polymer (A), the acid generating agent (B) and the like. The resin composition may contain one, or two or more types of the solvent (C).

The solvent (C) is exemplified by an alcohol solvent, an ether solvent, a ketone organic solvent, an amide solvent, an ester organic solvent, a hydrocarbon solvent, and the like.

Of these, the solvent (C) contained in the radiation-sensitive composition (I) is preferably the ester solvent or the ketone solvent, more preferably a polyhydric alcohol partial ether carboxylate solvent or a cyclic ketone solvent, still more preferably a polyhydric alcohol partial alkyl ether acetate or a cycloalkanone, and particularly preferably propylene glycol monomethyl ether acetate or cyclohexanone.

### Other Components

The other component is exemplified by a crosslinking agent, a surfactant, and the like.

### Crosslinking Agent

The crosslinking agent is a component capable of forming a crosslinking bond between components such as molecules of the polymer (A), or capable of forming a cross-linked structure per se, by an action of heat, an acid, and/or the like. When the radiation-sensitive composition (I) contains the crosslinking agent, an increase in hardness of the coating film of the radiation-sensitive composition (I) to be formed is enabled. The radiation-sensitive composition (I) may contain one, or two or more types of the crosslinking agent.

The crosslinking agent is exemplified by a polyfunctional (meth)acrylate compound, an epoxy compound, a hydroxymethyl group-substituted phenol compound, an alkoxyalkyl group-containing phenol compound, a compound having an alkoxyalkylated amino group, a random copolymer of acenaphthylene and hydroxymethylacenaphthylene, and the like.

Examples of the polyfunctional (meth)acrylate compound include trimethylolpropane tri(meth)acrylate, pentaerythritol tri(meth)acrylate, dipentaerythritol penta(meth)acrylate, and the like.

Examples of the epoxy compound include a novolak-type epoxy resin, a bisphenol type epoxy resin, an alicyclic epoxy resin, an aliphatic epoxy resin, and the like.

Examples of the hydroxymethyl group-substituted phenol compound include 2-hydroxymethyl-4,6-dimethylphenol, 3,5-dihydroxymethyl-4-methoxytoluene (2,6-bis(hydroxymethyl)-p-cresol), and the like.

Examples of the alkoxyalkyl group-containing phenol compound include 4,4′-(1-(4-(1-(4-hydroxy-3,5-bis(methoxymethyl)phenyl)-1-methylethyl)phenyl)ethylidene)bis(2,6-bis(methoxymethyl)phenol and the like.

Examples of the compound having an alkoxyalkylated amino group include (poly)methylol melamine, (poly)methylol glycoluril, and the like.

The crosslinking agent is preferably the alkoxyalkyl group-containing phenol compound, and more preferably 4,4′ -(1-(4-(1-(4-hydroxy-3,5-bis(methoxymethyl)phenyl)-1-methylethyl)phenyl)ethylidene)bis(2,6-bis(methoxymethyl)phenol.

In the case in which the radiation-sensitive composition (I) contains the crosslinking agent, a content of the crosslinking agent with respect to 100 parts by mass of the polymer (A) is preferably no less than 1 part by mass, and more preferably no less than 10 parts by mass. The content of the crosslinking agent is preferably no greater than 70 parts by mass, and more preferably no greater than 30 parts by mass. When the content of the crosslinking agent falls within the above range, hardness of the coating film of the radiation-sensitive composition (I) can be further increased.

### Surfactant

The surfactant is a component capable of improving coating properties of the radiation-sensitive composition (I) on the surface of the substrate.

In the case in which the radiation-sensitive composition (I) contains the surfactant, a content thereof with respect to 100 parts by mass of the polymer (A) is preferably no greater than 10 parts by mass, and more preferably no greater than 1 part by mass. Typically, the content of the surfactant is no less than 0.1 parts by mass.

### Preparation Procedure of Radiation-Sensitive Composition (I)

The radiation-sensitive composition (I) may be prepared, for example, by mixing the polymer (A) and the acid generating agent (B), as well as the other component(s) such as the solvent (C) which may be added as needed, in a certain ratio, and preferably filtering a thus resulting mixture through a filter having a pore size of no greater than 0.2 μm.

### Heating Step

It is preferred that the pattern-forming method further includes a heating step before the exposing step described later. In this step, the coating film formed by the applying step is heated. It is considered that the heating step results in an interaction of the surface of the substrate with the polymer (A) of the radiation-sensitive composition (I) via a hydrogen bond, thereby leading to lamination of the coating film of the radiation-sensitive composition containing the polymer (A) to the surface of the substrate.

Means for heating is exemplified by an oven, a hot plate, and the like. A temperature of the heating is preferably no less than 80° C., more preferably no less than 150° C., and still more preferably no less than 180° C. The temperature of the heating is preferably no greater than 400° C., more preferably no greater than 300° C., and still more preferably no greater than 250° C. A time period of the heating is preferably no less than 10 sec, more preferably no less than 1 min, and still more preferably no less than 3 min. The time period of the heating is preferably no greater than 120 min, more preferably no greater than 30 min, and still more preferably no greater than 10 min.

It is preferred that in the heating step, the coating film of the radiation-sensitive composition is washed with an organic solvent such as PGMEA after the heating.

An average thickness of the coating film of the radiation-sensitive composition to be formed can be brought to a desired value by appropriately selecting: the type and concentration of the polymer (A) in the radiation-sensitive composition (I); conditions in the heating step such as a temperature of heating and a time period of heating; conditions in a desorbing step such as the type and concentration of the organic solvent, and the number of times of repeating the washing; and the like. A film thickness of the coating film of the radiation-sensitive composition on the surface of the substrate is preferably no less than 5 nm, more preferably no less than 10 nm, and still more preferably no less than 20 nm. The film thickness of the coating film is preferably no greater than 200 nm, more preferably no greater than 100 nm, and still more preferably no greater than 50 nm.

### Exposing Step

Next, in the exposing step, exposure is carried out by irradiating a desired region of the coating film with a radioactive ray through a mask having a specific pattern. The radioactive ray is exemplified by ultraviolet rays, far ultraviolet rays, X-rays, charged particle rays, and the like. Of these, far ultraviolet rays typified by an ArF excimer laser beam and a KrF excimer laser beam are preferred, and an ArF excimer laser beam is more preferred. Also, liquid immersion lithography may be carried out as an exposure procedure. In the exposing step, an acid is generated from the acid generating agent in a light-exposed region by irradiation with the radioactive ray, and this acid deactivates the side chain group (I) of the polymer derived from the structural unit (I) of the polymer (A) having been grafted on the surface of the substrate, thereby leading to a failure of grafting of the polymer (A) on the surface of the substrate. Meanwhile, since grafting of the polymer (A) of the light-unexposed region is maintained on the surface of the substrate, the pattern is formed on the surface of the substrate.

It is to be noted that, for the purpose of promoting the desorption of the polymer derived from the structural unit (I) of the polymer (A) by the acid generated from the acid generating agent, post exposure baking (PEB) may be carried out after the exposing.

The pattern-forming method may also include, after the exposing step, a heating step for heating the coating film formed by the applying step. In the case in which the heating step is carried out after the exposing step, only the polymer derived from the structural unit (I) of the polymer (A) in the light-unexposed region where the side chain group (I) remains active can be grafted on the surface of the substrate.

### Developing Step

In the developing step, the coating film after the heating step and the exposing step is developed. The developing step enables the polymer (A) in the light-exposed region on the surface of the substrate to be selectively desorbed. As a result, a fine pattern can be conveniently formed. As a developer solution for use in the pattern-forming method of the embodiment of the present invention, for example, an organic solvent such as propylene glycol monomethyl ether acetate (PGMEA) may be preferably used.

A static contact angle of pure water on the surface of the pattern is preferably no less than 80°, and more preferably no less than 90°. The static contact angle is preferably no greater than 120°, and more preferably no greater than 110°. When the static contact angle on the surface of the coating film falls within the above range, orientation characteristics of the phase separation structure by directed self-assembly can be further improved in the case in which the pattern described above is used as the guide pattern.

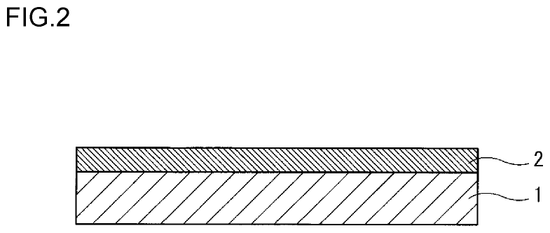

In the following, a specific production example of a guide pattern in the pattern-forming method of the embodiment of the present invention will be described with reference to FIGS. 2 to 5.

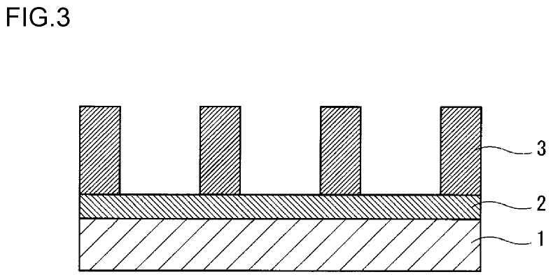

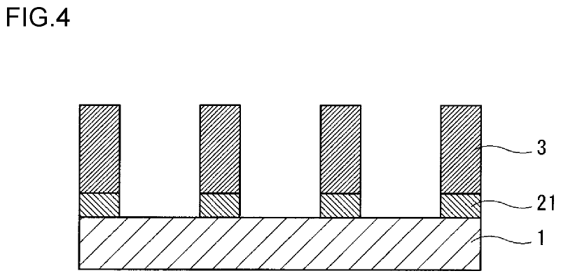

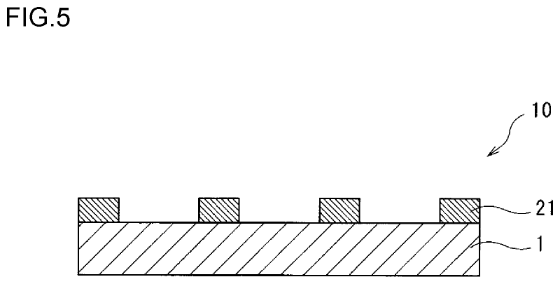

First, as shown in FIG. 2, the radiation-sensitive composition (I) is applied on a substrate 1 by the applying step and thereafter a coating film is heated by the heating step, thereby laminating a coating film 2 on the surface of the substrate 1. Next, as shown in FIG. 3, a pattern 3 for a mask is formed in a certain region of the coating film 2, and the exposing step is carried out. Next, in the developing step, as shown in FIG. 4, the coating film 2 is etched through the pattern 3 for the mask. Then, as shown in FIG. 5, the pattern 3 for the mask is etched, thereby enabling a substrate 10 with a guide pattern 21 having been formed thereon to be obtained.

### Fine Pattern-Forming Step by Guide Pattern

The pattern-forming method of the embodiment of the present invention may further include a fine pattern-forming step with a guide pattern. In this step, a fine pattern constituted from a directed self-assembling material containing a block copolymer is formed, using as a guide pattern the pattern formed by the pattern-forming method described above. Due to including the fine pattern-forming step with a guide pattern, the pattern-forming method enables improvement of throughput in a fine pattern-forming process in a case of conducting the directed self-assembly with a chemo-epitaxy process, and formation of the guide pattern superior in orientation characteristics of the phase separation structure by directed self-assembly is enabled.

In the fine pattern-forming step with a guide pattern, a pattern configuration obtained by phase separation in the directed self-assembling material is controlled by the guide pattern, thereby enabling formation of a desired fine pattern. More specifically, with respect to the guide pattern, due to the components in the guide pattern, the guide pattern appropriately interacts with the directed self-assembling film. Therefore, among blocks included in the block copolymer contained in the directed self-assembling material, the blocks having higher affinity to the guide pattern form a phase along the guide pattern, while blocks having lower affinity to the guide pattern form a phase at a position spaced apart from the guide pattern. Thus, formation of a desired pattern is enabled. Furthermore, selecting the material, size, shape and the like of the guide pattern enables meticulous control of a structure of the pattern to be obtained by the phase separation in the directed self-assembling material. It is to be noted that the shape, size and the like of the guide pattern may be appropriately selected in accordance with the desired pattern to be ultimately formed, and for example, a line-and-space pattern, a hole pattern, and the like may be employed.

According to the pattern-forming method, a fine pattern can be conveniently formed. Moreover, in a case in which directed self-assembly is carried out with the chemo-epitaxy process, the pattern-forming method enables improvement of throughput in a fine pattern-forming process and formation of a guide pattern which is superior in orientation characteristics of the phase separation structure by directed self-assembly. Moreover, since a chemical amplification effect with a radiation-sensitive acid generating agent that is capable of generating an acid by exposure is not utilized, formation of a pattern with high resolution is enabled.

### Radiation-Sensitive Composition

The radiation-sensitive composition of the embodiment of the present invention contains: a polymer having a first structural unit represented by the above formula (1) at no less than one end of a main chain thereof and the radiation-sensitive acid generating agent described above. Due to containing the polymer having the first structural unit at no less than one end of a main chain thereof, and the radiation-sensitive acid generating agent, the radiation-sensitive composition can be suitably used for an intended usage in which a fine pattern is to be conveniently formed.

Furthermore, it is preferred that the polymer further has a structural unit that is different from the first structural unit and is the structural unit represented by the above formula (2-1), the structural unit represented by the above formula (2-2), or a combination thereof.

The radiation-sensitive composition of the embodiment of the present invention has been described above as the radiation-sensitive composition (I) in the pattern-forming method of the embodiment of the present invention.

### EXAMPLES

Hereinafter, the present invention is explained in detail by way of Examples, but the present invention is not in any way limited to these Examples. Measuring methods for each physical property are shown below.

### Mw and Mn

The Mw and the Mn of the polymer were determined by gel permeation chromatography (GPC) using GPC columns (Tosoh Corporation; “G2000 HXL”×2, “G3000 HXL”×1 and “G4000 HXL”×1) under the following conditions:

eluent: tetrahydrofuran (Wako Pure Chemical Industries, Ltd.);

flow rate: 1.0 mL/min;

sample concentration: 1.0% by mass;

amount of sample injected: 100 μL;

column temperature: 40° C.;

detector: differential refractometer; and

standard substance: mono-dispersed polystyrene.

### ¹³C-NMR Analysis

A ¹³C-NMR analysis was performed using a nuclear magnetic resonance apparatus (“JNM-EX400” available from JEOL, Ltd.), with DMSO-d₆ used as a solvent for measurement. The proportion of each structural unit contained in the polymer was calculated from an area ratio of a peak corresponding to each structural unit on the spectrum obtained by the ¹³C-NMR.

### Synthesis of Polymer (A)

### Synthesis Example 1: Synthesis of Polymer (A-1)

After a 500-mL flask as a reaction vessel was dried under reduced pressure, 120 g of tetrahydrofuran which had been subjected to a distillation dehydrating treatment in a nitrogen atmosphere was charged, and cooled to −78° C. Thereafter, 0.42 mL of a 1 N cyclohexane solution of sec-butyllithium (sec-BuLi) was charged into this tetrahydrofuran. Thereafter, 13.3 mL of styrene which had been subjected to: adsorptive filtration by means of silica gel for removing the polymerization inhibitor; and a dehydration treatment by distillation was added dropwise over 30 min and then the mixture was stirred for 30 min. Furthermore, 0.17 mL of 1,1-diphenylethylene and 1.64 mL of a 0.5 N tetrahydrofuran solution of lithium chloride were added thereto, and the color of the mixture was ascertained to be dark red. Thereafter, 0.60 mL of N,N-dimethylaminoethyl methacrylate was added thereto and the mixture was stirred for 1 hour. Then, 1 mL of methanol was charged to allow for a terminating reaction of the polymerization end. The temperature of the reaction mixture was elevated to room temperature, and a reaction solution thus obtained was concentrated and the solvent was replaced with methyl isobutyl ketone. An operation of charging 500 g of ultra pure water to the liquid, stirring the mixture followed by allowing to stand still, and removing the aqueous underlayer was repeated six times. Then the aqueous layer was confirmed to have become neutral. Thereafter, a remaining solution was concentrated and added dropwise into 500 g of methanol to allow the polymer to be precipitated. The solid was collected using a Buechner funnel. This solid was dried at 60° C. under reduced pressure to give 11.3 g of a white polymer represented by the following formula (A-1).

With respect to this polymer (A-1), the Mw was 30,000, the Mn was 28,000, and the Mw/Mn was 1.07. As determined by the ¹³C-NMR analysis with respect to the proportion of the structural unit contained, a styrene-derived block was 97 mol % and an N,N-dimethylaminoethyl methacrylate-derived block was 3 mol %, revealing that in the polymer (A-1), the N,N-dimethylaminoethyl methacrylate-derived block had bonded adjacent to the styrene-derived block, as represented by the following formula (A-1).

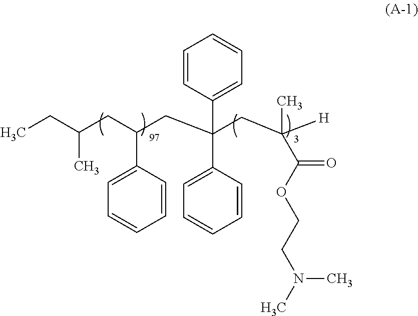

### Preparation of Radiation-Sensitive Composition (I)

A radiation-sensitive composition (I-1) was prepared by mixing: as the polymer (A), 100 parts by mass of the polymer (A-1) obtained in the Synthesis Example 1; as the acid generating agent (B), 20 parts by mass of triphenylsulfonium nonafluoro-n-butanesulfonate as the radiation-sensitive acid generating agent; and as the solvent (C), 16,500 parts by mass of propylene glycol monomethyl ether acetate (PGMEA), and filtering a resulting mixed solution through a membrane filter having a pore size of 200 nm.

### Formation of Coating Film

### Example 1

Two pieces of a silicon dioxide (SiO₂) substrate were provided, and on each of the surfaces of the substrate, the radiation-sensitive composition (I-1) was applied with spin coating (1,500 rpm, for 30 sec) to form a coating film. As a result of a measurement of a film thickness of the coating film at this point in time by an ellipsometer (“alpha-SE”, available from J. A. Woollam Co.), formation of a coating film of 30 nm on SiO₂ was verified. One of the two pieces of the substrates on which the coating film had been formed was baked at 175° C. for 5 min and thereafter washed with PGMEA. The film thickness was measured again with the ellipsometer, and the coating film had a film thickness of 7.3 nm. Next, a static contact angle of pure water on the surface of the coating film measured by using a contact angle scale was verified to be 91°. In addition, another substrate was irradiated at 10 mJ with light having a wavelength of 254 nm by using an apparatus by which exposure is executed without attaching a mask holder, baked at 175° C. for 5 min and then washed with PGMEA. After the washing, the absence of any remaining coating film on the surface of the substrate was ascertained. Moreover, a static contact angle of pure water on the surface of the substrate measured by using the contact angle scale was 52°.

In Example 1, the polymer (A) was grafted on the surface of the substrate in the light-unexposed region, whereas no coating film remained in the light-exposed region. Thus, it was indicated that the radiation-sensitive composition (I-1) used in the Example 1 served as a radiation-sensitive composition suitable for a pattern-forming method. Moreover, since the static contact angle on the surface of the coating film in the light-unexposed region was 91°, and the static contact angle on the surface of the coating film in the light-exposed region was 52°, it was suggested that the pattern obtained in the Example 1 serves as a guide pattern for forming a fine pattern constituted from such a directed self-assembling material containing a block copolymer as PS (polystyrene)-block-PMMA (polymethyl methacrylate).

According to the pattern-forming method and the radiation-sensitive composition of the embodiments of the present invention, a fine pattern can be conveniently formed. Moreover, in a case in which directed self-assembly is carried out with a chemo-epitaxy process, improvement of throughput in a fine pattern-forming process is enabled, and formation of a guide pattern which is superior in orientation characteristics of the phase separation structure by directed self-assembly is enabled. Therefore, the pattern-forming method can be suitably used for working processes of semiconductor devices, and the like, in which microfabrication is expected to be further in progress hereafter.

Obviously, numerous modifications and variations of the present invention are possible in light of the above teachings. It is therefore to be understood that within the scope of the appended claims, the invention may be practiced otherwise than as specifically described herein.

What is claimed is:

1. A pattern-forming method comprising:
applying a radiation-sensitive composition comprising a polymer and a radiation-sensitive acid generating agent on a surface of a substrate to form a coating film on the surface of the substrate;
exposing the coating film; and
developing the coating film exposed,
wherein
the polymer comprises a first structural unit represented by formula (1): 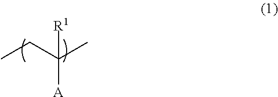
wherein, in the formula (1), R¹ represents a hydrogen atom, a methyl group, a fluorine atom, or a trifluoromethyl group; and A represents a monovalent organic group having a nitrogen atom.

2. The pattern-forming method according to claim 1, wherein the polymer comprises the first structural unit at at least one end of a main chain thereof.

3. The pattern-forming method according to claim 1, wherein the polymer further comprises a second structural unit that is different from the first structural unit and that is a structural unit represented by formula (2-1), a structural unit represented by formula (2-2) or a combination thereof, 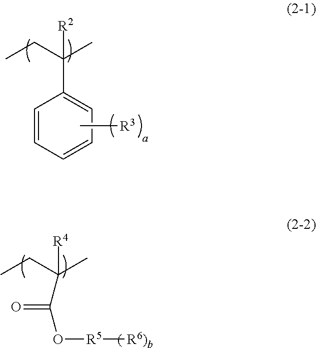
wherein, in the formulae (2-1) and (2-2), R² and R⁴ each independently represent a hydrogen atom, a methyl group, a fluorine atom, or a trifluoromethyl group; R³ represents a monovalent organic group having 1 to 20 carbon atoms; R⁵ represents a hydrocarbon group having 1 to 20 carbon atoms and having a valency of (1+b); R⁶ represents a hydrogen atom or a monovalent group having a hetero atom; a is an integer of 0 to 5, wherein in a case in which a is no less than 2, a plurality of R³s are identical or different from each other; and b is an integer of 1 to 3, wherein in a case in which b is no less than 2, a plurality of R⁶s are identical or different from each other.

4. The pattern-forming method according to claim 1, further comprising, before the exposing or after the exposing, and before the developing, heating the coating film.

5. The pattern-forming method according to claim 1, wherein A in the formula (1) represents a group represented by formula (i): 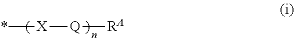
wherein X represents a single bond, —COO—, —CO—, —O—, —NH—, —NHCO— or —CONH—; Q represents a single bond or a divalent hydrocarbon group having 1 to 20 carbon atoms; R^{A} represents a monovalent primary, secondary or tertiary amino group having 0 to 20 carbon atoms, or a monovalent nitrogen-containing heterocyclic group having 5 to 20 ring atoms; n is an integer of 0 to 10, wherein in a case in which n is no less than 1, Q does not represent a single bond; and * denotes a binding site to the carbon atom to which R¹ bonds in the formula (1).

6. The pattern-forming method according to claim 5, wherein R^{A} in the formula (i) represents a monovalent primary or tertiary amino group having 0 to 20 carbon atoms, or a monovalent nitrogen-containing heterocyclic group having 5 to 20 ring atoms.

7. A pattern-forming method comprising forming a fine pattern constituted from a directed self-assembling material comprising a block copolymer, using the pattern formed by the pattern-forming method according to claim 1 as a guide pattern.

8. The pattern-forming method according to claim 7, wherein the polymer included in the radiation-sensitive composition comprises the first structural unit at at least one end of a main chain thereof.

9. The pattern-forming method according to claim 7, wherein the polymer included in the radiation-sensitive composition further comprises a second structural unit that is different from the first structural unit and that is a structural unit represented by formula (2-1), a structural unit represented by formula (2-2) or a combination thereof, 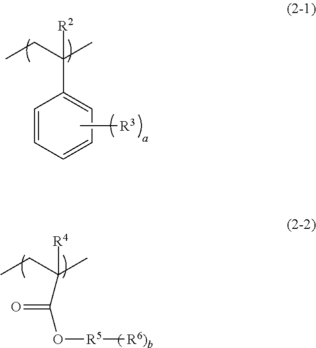
wherein, in the formulae (2-1) and (2-2), R² and R⁴ each independently represent a hydrogen atom, a methyl group, a fluorine atom, or a trifluoromethyl group; R³ represents a monovalent organic group having 1 to 20 carbon atoms; R⁵ represents a hydrocarbon group having 1 to 20 carbon atoms and having a valency of (1+b); R⁶ represents a hydrogen atom or a monovalent group having a hetero atom; a is an integer of 0 to 5, wherein in a case in which a is no less than 2, a plurality of R³s are identical or different from each other; and b is an integer of 1 to 3, wherein in a case in which b is no less than 2, a plurality of R⁶s are identical or different from each other.

10. The pattern-forming method according to claim 7, wherein A in the formula (1) represents a group represented by formula (i): 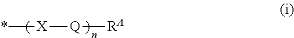
wherein X represents a single bond, —COO—, —CO—, —O—, —NH—, —NHCO— or —CONH—; Q represents a single bond or a divalent hydrocarbon group having 1 to 20 carbon atoms; R^{A} represents a monovalent primary, secondary or tertiary amino group having 0 to 20 carbon atoms, or a monovalent nitrogen-containing heterocyclic group having 5 to 20 ring atoms; n is an integer of 0 to 10, wherein in a case in which n is no less than 1, Q does not represent a single bond; and * denotes a binding site to the carbon atom to which R¹ bonds in the formula (1).

11. The pattern-forming method according to claim 10, wherein R^{A} in the formula (i) represents a monovalent primary or tertiary amino group having 0 to 20 carbon atoms, or a monovalent nitrogen-containing heterocyclic group having 5 to 20 ring atoms.

12. A radiation-sensitive composition comprising:
a polymer comprising a first structural unit represented by formula (1) at at least one end of a main chain thereof; and
a radiation-sensitive acid generating agent, 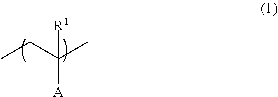
wherein, in the formula (1), R¹ represents a hydrogen atom, a methyl group, a fluorine atom, or a trifluoromethyl group; and A represents a monovalent organic group having a nitrogen atom.

13. The radiation-sensitive composition according to claim 12, wherein the polymer further comprises a second structural unit that is different from the first structural unit and that is a structural unit represented by formula (2-1), a structural unit represented by formula (2-2) or a combination thereof, 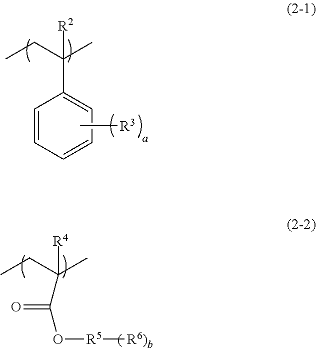
wherein, in the formulae (2-1) and (2-2), R² and R⁴ each independently represent a hydrogen atom, a methyl group, a fluorine atom, or a trifluoromethyl group; R³ represents a monovalent organic group having 1 to 20 carbon atoms; R⁵ represents a hydrocarbon group having 1 to 20 carbon atoms and having a valency of (1+b); R⁶ represents a hydrogen atom or a monovalent group having a hetero atom; a is an integer of 0 to 5, wherein in a case in which a is no less than 2, a plurality of R¹s are identical or different from each other; and b is an integer of 1 to 3, wherein in a case in which b is no less than 2, a plurality of R⁶s are identical or different from each other.

14. The radiation-sensitive composition according to claim 12, wherein A in the formula (1) represents a group represented by formula (i): 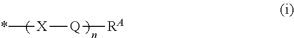
wherein X represents a single bond, —COO—, —CO—, —O—, —NH—, —NHCO— or —CONH—; Q represents a single bond or a divalent hydrocarbon group having 1 to 20 carbon atoms; R^{A} represents a monovalent primary, secondary or tertiary amino group having 0 to 20 carbon atoms, or a monovalent nitrogen-containing heterocyclic group having 5 to 20 ring atoms; n is an integer of 0 to 10, wherein in a case in which n is no less than 1, Q does not represent a single bond; and * denotes a binding site to the carbon atom to which R¹ bonds in the formula

15. The radiation-sensitive composition according to claim 14, wherein R^{A} in the formula (i) represents a monovalent primary or tertiary amino group having 0 to 20 carbon atoms, or a monovalent nitrogen-containing heterocyclic group having 5 to 20 ring atoms.
